(19) United States
(12) Patent Application Publication
(10) Pub. No.: US 2014/0333354 A1
(43) Pub. Date: Nov. 13, 2014

(54) CHARGE PUMP, A PHASE LOCKED LOOP CIRCUIT AND A CHARGE PUMP METHOD

(71) Applicant: Beken Corporation, Shanghai (CN)

(72) Inventors: Mingsheng Ao, Shanghai (CN); Dawei Guo, Shanghai (CN); Jianqin Zheng, Shanghai (CN)

(21) Appl. No.: 13/913,391

(22) Filed: Jun. 8, 2013

(30) Foreign Application Priority Data
May 8, 2013 (CN) 201310170135.8

(51) Int. Cl. H03L 7/08

(52) U.S. Cl. CPC H03L 7/08
USPC 327/157

(57) ABSTRACT

The invention discloses a charge pump, a phase locked loop circuit and a charge pump method. The charge pump comprises an input port, a switch and an output port. The input port receives a phase frequency adjustment parameter. The switch switches a first current on or off, according to the phase frequency adjustment parameter, and keeps a second current on. The first current is larger than the second current. The output port outputs a sum of the first current and the second current to a low pass filter.

### CLAIM OF PRIORITY

This application claims priority to Chinese Application No. 201310170135.8 entitled “A CHARGE PUMP, A PHASE LOCKED LOOP CIRCUIT AND A CHARGE PUMP METHOD”, filed on May 8, 2013 by Beken Corporation, which is incorporated herein by reference.

### TECHNICAL FIELD

The present application relates to electrostatic circuits, and more particularly but not exclusive to a charge pump, a phase locked loop circuit and a method in the charge pump.

### BACKGROUND

A phase-locked loop (PLL) is a control system that generates an output signal, also called a F_N clock, whose phase is related to the phase of an input “reference” signal, also called a F_ref clock.

The PLL comprises a charge pump, and the charge pump faces problems such as a mismatch between charge current and discharge current. Therefore charge pumps need to be improved.

### SUMMARY OF THE INVENTION

In an embodiment, a charge pump comprises an input port, a switch and an output port. The input port receives a phase frequency adjustment parameter. The switch switches a first current on or off, according to the phase frequency adjustment parameter, and keeps a second current on, wherein the first current is larger than the second current. The output port outputs a sum of the first current and the second current to a low pass filter.

In another embodiment, a charge pump method comprises receiving a phase frequency adjustment parameter; switching a first current on or off, according to the phase frequency adjustment parameter; keeping a second current always on, wherein the first current is larger than the second current; and outputting a sum of the first current and the second current to a low pass filter.

In another embodiment, a PLL comprises a phase frequency detector, a charge pump, a low pass filter, a voltage controlled oscillator (VCO), and a frequency divider. The phase frequency detector receives a first input signal and a second input signal. The phase frequency detector further outputs a first phase frequency adjustment parameter and a second phase frequency adjustment parameter according to phase and frequency difference between the first input signal and the second input signal. The charge pump is coupled to the phase frequency detector. The charge pump receives one of the first phase frequency adjustment parameter and the second adjustment. The charge pump switches a first current on or off, according to the received phase frequency adjustment parameter; and keeps a second current on, wherein the first current is larger than the second current. The charge pump then outputs a sum of the first current and the second current to a low pass filter. The low pass filter generates a voltage according to the sum of the first current and the second current. The voltage controlled oscillator (VCO) coupled to the low pass filter. The VCO generates an oscillation frequency according to the voltage. The frequency divider receives the oscillation frequency, divides the oscillation frequency, and generates the second input signal using the divided oscillation frequency.

### BRIEF DESCRIPTION OF THE DRAWINGS

Non-limiting and non-exhaustive embodiments of the present invention are described with reference to the following figures, wherein like reference numerals refer to like parts throughout the various views unless otherwise specified.

FIG. 1 shows a schematic diagram of a phase locked loop according to an embodiment of the invention.

FIG. 2 shows a block diagram of the charge pump according to an embodiment of the invention.

FIG. 3 shows a detailed structure for the charge pump according to a first embodiment of the invention.

FIG. 4 shows illustrative currents generated by the charge pump according to the first embodiment of the invention.

FIG. 5 shows a detailed structure for the charge pump according to a second embodiment of the invention.

FIG. 6 shows illustrative currents generated by the charge pump according to a second embodiment of the invention.

FIG. 7 shows a flow chart according to an embodiment of the invention.

### DETAILED DESCRIPTION OF THE ILLUSTRATED EMBODIMENTS

Various aspects and examples of the invention will now be described. The following description provides specific details for a thorough understanding and enabling description of these examples. Those skilled in the art will understand, however, that the invention may be practiced without many of these details. Additionally, some well-known structures or functions may not be shown or described in detail, so as to avoid unnecessarily obscuring the relevant description.

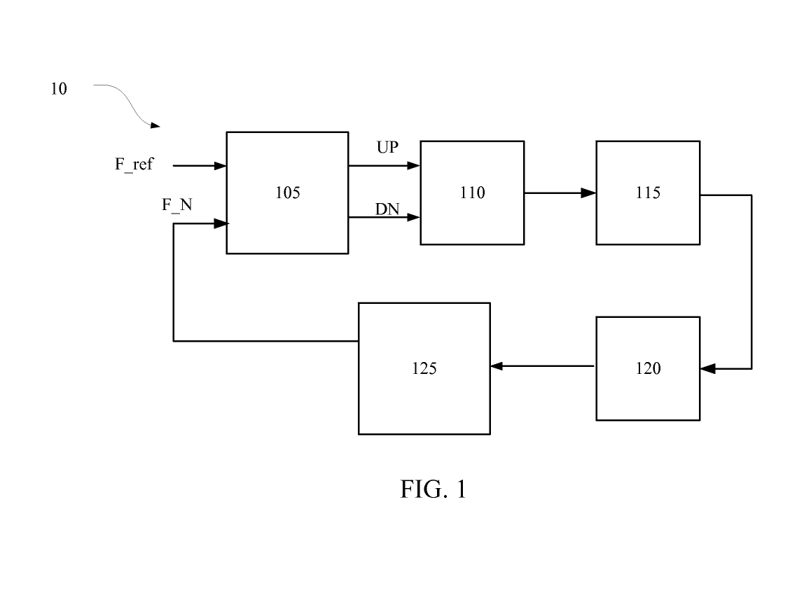

As shown in FIG. 1, a phase locked loop (PLL) circuit 10 comprises a phase frequency detector (PFD) 105, a charge pump (CP) 110, a low pass filter (LPF) 115, a voltage controlled oscillator (VCO) 120 and a frequency divider (FD) 125.

The phase frequency detector 105 is configured to receive a first input signal F_ref and a second input signal F_N. The phase frequency detector 105 then outputs a first phase frequency adjustment parameter, marked as UP (up) in FIG. 1, and a second phase frequency adjustment parameter, marked as DN (down) in FIG. 1, according to a phase and frequency difference between the first input signal F_ref and the second input signal F_N. The first input signal comprises a F_ref clock signal (marked as F_ref in FIG. 1), and the second input signal comprises a F_N clock signal (marked as F_N in FIG. 1). The difference between the first phase frequency adjustment parameter UP and the second phase frequency adjustment parameter DN is proportional to the phase and frequency difference between the first input signal F_ref and the second input signal F_N.

The charge pump 110 is coupled to the phase frequency detector 105, and is configured to receive one of the first phase frequency adjustment parameter UP and the second adjustment DN. The charge pump 110 then switches a first current on or off, according to the received phase frequency adjustment parameter. The charge pump 110 keeps a second current on. The first current is larger than the second current. The charge pump 110 further outputs a sum of the first current and the second current to the low pass filter 115.

Alternatively, the first current and the second current are configured to satisfy the following equation that the product of the value of the first current (I_{big}) and the minimum phase error (Pe(min)) is smaller than the product of the value of the second current (Iₛₘₐₗₗ) and the period of the reference signal (T_{ref}), that is, I_{big}×Pe(min)<I_{small×T}_{ref}. Wherein, T_{ref} represents the period of the reference signal, that is, the period of the first input signal F_ref.

It should be appreciated by those skilled in the art that the equation of I_{big}×Pe(min)<Iₛₘₐₗₗ×T_{ref} is satisfied.

For example, assume a case that F_N>F_ref, and Iₛₘₐₗₗ is used as charging current, and I_{big} is used as discharging current. Iₛₘₐₗₗ is constant. I_{big} is variable, which is controlled by the second phase frequency adjustment parameter DN outputted by PFD 105. If the charge pump needs to discharge electricity, the pulse width of DN increases, and the pulse width of DN is larger than the minimum phase error Pe(min) Therefore I_{big}×pulsewidth of DN>Iₛₘₐₗₗ×T_{ref}. That means, electricity charged by Iₛₘₐₗₗ is smaller than electricity discharged by I_{big}, such that the charge pump discharges electricity. However, I_{big}×Pe(min)<Iₛₘₐₗₗ×T_{ref} should be satisfied.

Alternatively, assume a case that F_N>F_ref, and Iₛₘₐₗₗ is used as discharging current, and I_{big} is used as charging current. Wherein Iₛₘₐₗₗ is constant. I_{big} is variable, which is controlled by the first phase frequency adjustment parameter UP outputted by PFD 105. If the charge pump needs to discharge electricity, the pulse width of the first phase frequency adjustment parameter UP reaches the minimum Pe(min). When I_{big}×Pe(min) <Iₛₘₐₗₗ×T_{ref} is satisfied, electricity discharged by Iₛₘₐₗₗ is more than electricity charged by I_{big}, such that the charge pump discharges electricity.

Alternatively, assume a case that F_N<F_ref, and Iₛₘₐₗₗ is used as charging current, and I_{big} is used as discharging current. Wherein Iₛₘₐₗₗ is constant. I_{big} is variable, which is controlled by the second phase frequency adjustment parameter DN outputted by PFD 105. If the charge pump needs to charge electricity, the pulse width of the second phase frequency adjustment parameter DN reaches the minimum Pe(min). When I_{big}×Pe(min) <Iₛₘₐₗₗ×T_{ref} is satisfied, electricity charged by Iₛₘₐₗₗ is more than electricity discharged by I_{big}, such that the charge pump charges electricity.

Alternatively, assume a case that F_N<F ref, and Iₛₘₐₗₗ is used as discharging current, and I_{big} is used as charging current. Wherein Iₛₘₐₗₗ is constant and I_{big} is variable, which is controlled by the first phase frequency adjustment parameter UP outputted by PFD 105. If the charge pump needs to charge electricity, the pulse width of UP increases, and the pulse width of UP is larger than the minimum phase error Pe(min). Therefore I_{big}×pulsewidth of UP>Iₛₘₐₗₗ×T_{ref}. That means, electricity discharged by Iₛₘₐₗₗ is smaller than electricity charged by I_{big}, such that the charge pump charges electricity. However, I_{big}×Pe(min)<Iₛₘₐₗₗ×T_{ref} should be satisfied.

Alternatively, the first current is N times the second current.

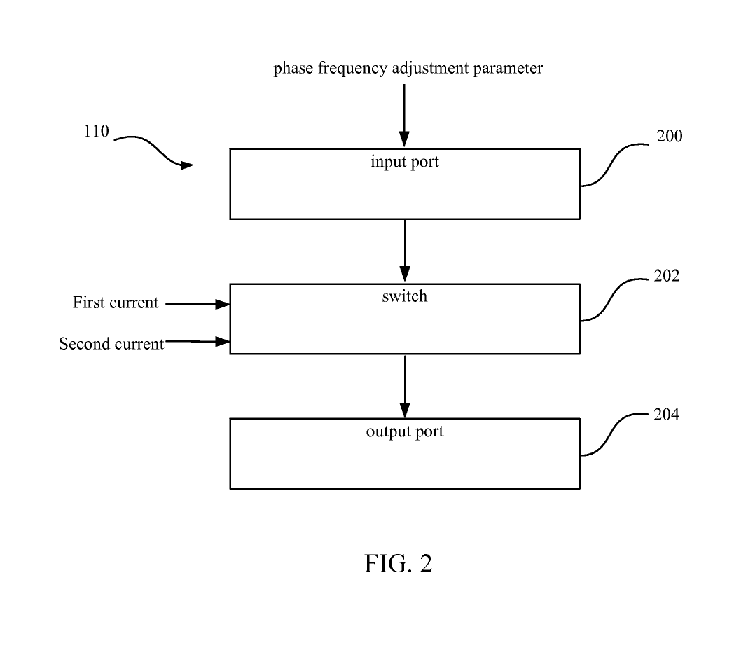

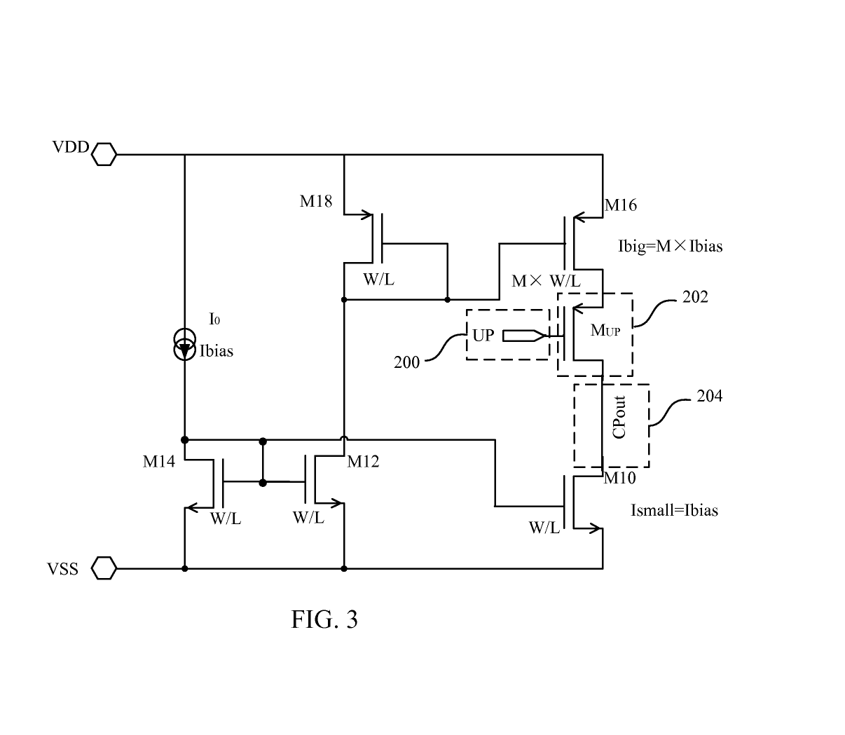

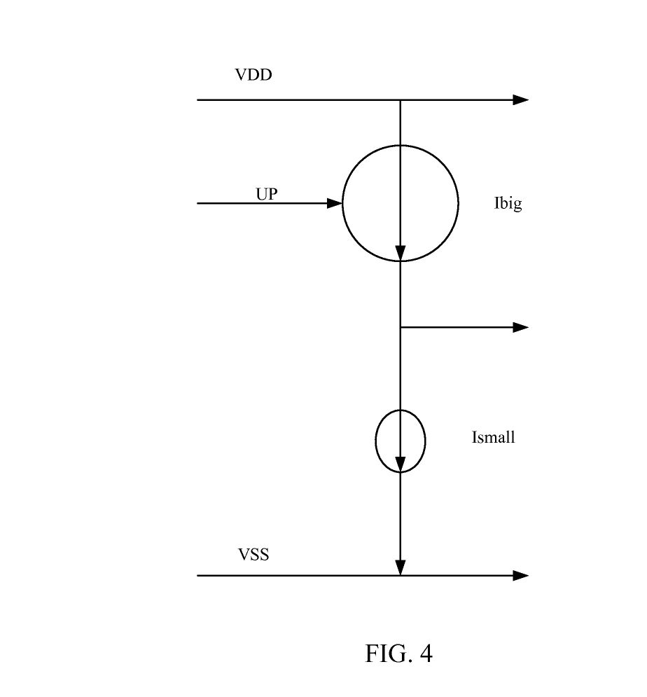

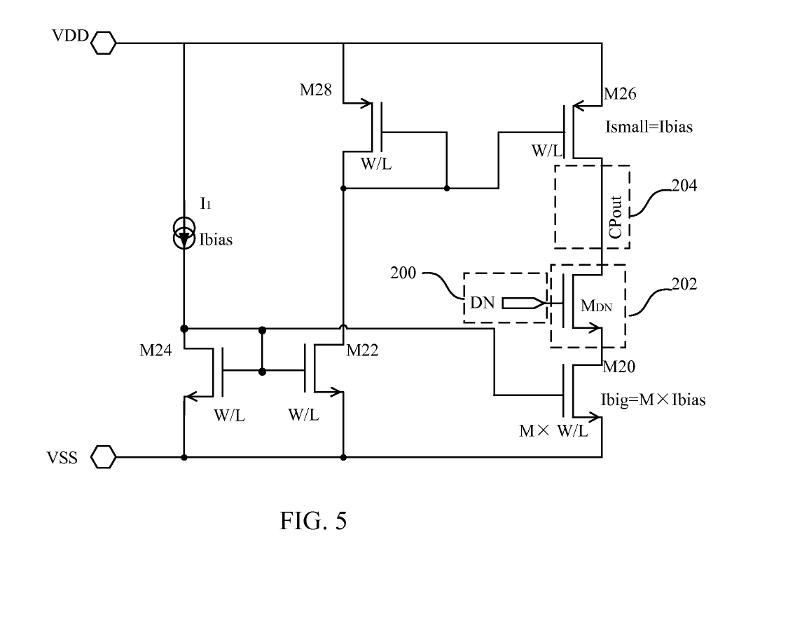

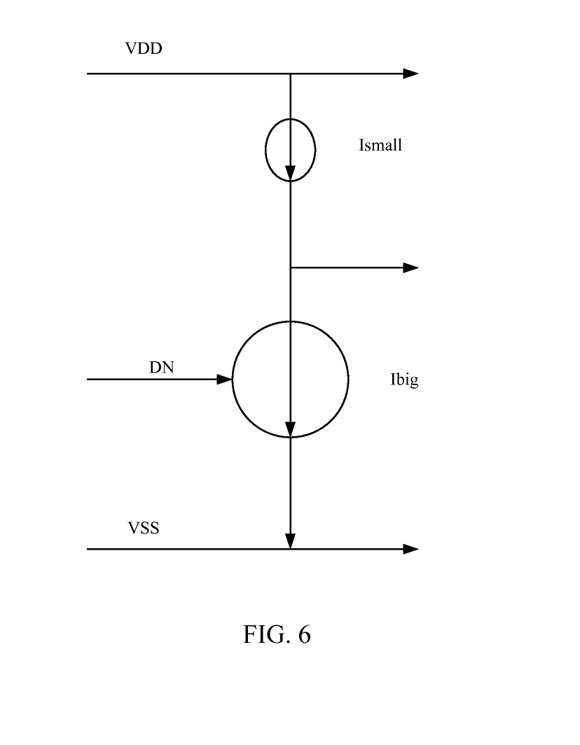

More detailed description of the operation of charge pump 110 will be given in embodiments with reference to the following FIG. 2, FIG. 3, FIG. 4, FIG. 5 and FIG. 6.

The low pass filter 115 is coupled to the charge pump 110. The low pass filter 115 is configured to generate a voltage according to the sum of the first current and the second current.

The voltage controlled oscillator 120 is coupled to the low pass filter 115. The voltage controlled oscillator 120 is configured to generate an oscillation frequency according to the voltage. The voltage controlled oscillator 120 may comprise a LC oscillator.

The frequency divider 125 is configured to receive the oscillation frequency from the voltage controlled oscillator 120. The frequency divider 125 divides the oscillation frequency by N, and generates the second input signal F_N using the divided oscillation frequency. Therefore the second input signal F_N equals the output frequency of the voltage controlled oscillator 120 divided by N.

FIG. 2 shows a block diagram of the charge pump 110. The charge pump 110 comprises an input port 200, a switch 202 and an output port 204. The input port 200 receives a phase frequency adjustment parameter UP or DN. The switch 202 switches a first current on or off, according to the phase frequency adjustment parameter, and keeps a second current on. The first current is larger than the second current. The output port 204 outputs a sum of the first current and the second current to a low pass filter.

FIG. 3 shows a detailed structure for the charge pump according to a first embodiment of the invention.

According to FIG. 3, the charge pump further comprises: a first current Source (I₀), a first NMOS (M10), a second NMOS (M12), a third NMOS (M14), a first PMOS (M16), a second PMOS (M18) and a PMOS switch (M_{UP}). The PMOS switch M_{UP} corresponds to the switch 202 in FIG. 2, shown as dashed block 202. A gate of the PMOS switch M_{UP} corresponds to the input port 200 in FIG. 2, shown as dashed block 200. A drain of the PMOS switch M_{UP} corresponds to the output port 204 in FIG. 2, shown as dashed block 204. The Sources of the first PMOS M16 and the second PMOS M18 are both connected to positive supply voltage (VDD). Gates of the first PMOS M16 and the second PMOS M18 and a drain of the second PMOS M18 are all connected to a drain of the second NMOS M12. A drain of the first PMOS M16 is connected to a source of the PMOS switch M_{UP}. Gates of the second NMOS M12 and the third NMOS M14, a drain of the third NMOS M14 and a gate of the first NMOS M10 are all connected to an output of the first current source I₀. Sources of the first NMOS M10, the second NMOS M12 and the third NMOS M14 are all connected to a negative supply voltage VSS. A drain of the first NMOS M10 is connected to a drain of the PMOS switch M_{UP}. The source of the PMOS switch M_{UP} is connected to the drain of the first PMOS M16. A gate of the PMOS switch M_{UP} receives the first phase frequency adjustment parameter UP, such that the PMOS switch M_{UP} switches on or off of the first PMOS M16. An output port CPout of the charge pump is at the drain of the first NMOS M10. Note that the drain of the first NMOS M10 is connected to the drain of the PMOS switch M_{UP}. It should be understood that the drain of the first NMOS M10 outputs a sum of the current (the second current Iₛₘₐₗₗ) passes through the first NMOS M10 and the current (the first current I_{big}) passes through the first PMOS M16. Although not shown in FIG. 3, it should be appreciated that low pass filter will provide DC operating point to the first NMOS M10, so that the first NMOS M10 will be on all the time. As shown in FIG. 3, current passes through the first PMOS M16 is I_{big} (which corresponds to the first current in FIG. 2), while current passes through the first NMOS M10 is Iₛₘₐₗₗ (which corresponds to the second current in FIG. 2).

Alternatively, the width versus length ratio (W/L) of the first PMOS M16 equals N times the width versus length ratio (W/L) of the first NMOS M10, and width versus length ratio of the first NMOS M10, second NMOS M12, third NMOS M14 and the second PMOS M18 are the same, as shown in FIG. 3. As current passes through the transistor is proportional to the width versus length ratio (W/L) of the transistor, the current I_{big} passes through the first PMOS M16 is M times the current Iₛₘₐₗₗ passes through the first NMOS M10.

FIG. 4 shows illustrative currents generated by the charge pump according to the first embodiment of the invention.

From FIG. 4, it is clear that I_{big} is controlled by the first phase frequency adjustment parameter UP, and therefore I_{big} is adjustable. Iₛₘₐₗₗ is constant. I_{big} is larger than Iₛₘₐₗₗ.

As shown in FIG. 5, in a second embodiment, the charge pump further comprises a second current source (I₁), a fourth NMOS (M20), a fifth NMOS (M22), a sixth NMOS (M24), a third PMOS (M26), a second PMOS (M28) and a NMOS switch (M_{DN}). The NMOS switch M_{DN} corresponds to the switch 202 in FIG. 2, shown as dashed block 202. A gate of the NMOS switch M_{DN} corresponds to the input port 200 in FIG. 2, shown as dashed block 200. A drain of the NMOS switch M_{DN} corresponds to the output port 204 in FIG. 2, shown as dashed block 204. Sources of the third PMOS M26 and the fourth PMOS M28 are both connected to a positive supply voltage (VDD). Gates of the third PMOS M26 and the fourth PMOS M28 and a drain of the fourth PMOS M28 are all connected to a drain of the fifth NMOS M22. A drain of the third PMOS M26 is connected to a source of the NMOS switch (M_{DN}). Gates of the fifth NMOS M22 and the sixth NMOS M24, a drain of the sixth NMOS M24 and a gate of the fourth NMOS M20 are all connected to an output of the second current source I₁. Sources of the fourth NMOS M20, the fifth NMOS M22 and the sixth NMOS M24 are all connected to a negative supply voltage VSS. A drain of the fourth NMOS M20 is connected to a source of the NMOS switch M_{DN}. A source of the NMOS switch M_{DN} is connected to a drain of the third PMOS M26. A gate of the NMOS switch M_{DN} receives the second phase frequency adjustment parameter DN, such that the NMOS switch M_{DN} switches on or off of the fourth NMOS M20, and an output port CPout of the charge pump is at the drain of the third PMOS M26. Note that the drain of the third PMOS M26 is connected to the drain of the NMOS switch M_{DN}. It should be understood that the drain of the third PMOS M26 outputs a sum of the current (the second current Iₛₘₐₗₗ) passes through the third PMOS M26 and the current (the first current I_{big}) passes through the fourth NMOS M20. Although not shown in FIG. 5, it should be appreciated that low pass filter will provide DC operating point to the third PMOS M26, so that the third PMOS M26 will be on all the time. As shown in FIG. 5, current passes through the third PMOS M26 is Iₛₘₐₗₗ (which corresponds to the second current in FIG. 2), while current passes through the fourth NMOS M20 is I_{big} (which corresponds to the first current in FIG. 2).

Alternatively, width versus length ratio (W/L) of the fourth NMOS M20 equals N times the width versus length ratio (W/L) of the third PMOS M26, and width versus length ratios (W/L) of the fourth NMOS M20, the fifth NMOS M22, the sixth NMOS M24 and the fourth PMOS M28 are the same, as shown in FIG. 5. As current passes through the transistor is proportional to the width versus length ratio (W/L) of the transistor, the current I_{big} passes through the fourth NMOS M20 is M times the current Iₛₘₐₗₗ passes through the third PMOS M26.

FIG. 6 shows an illustrative currents generated by the charge pump according to the second embodiment of the invention.

From FIG. 6, it is clear that I_{big} is controlled by the second phase frequency adjustment parameter DN, and therefore I_{big} is adjustable. Iₛₘₐₗₗ is constant. I_{big} is larger than Iₛₘₐₗₗ.

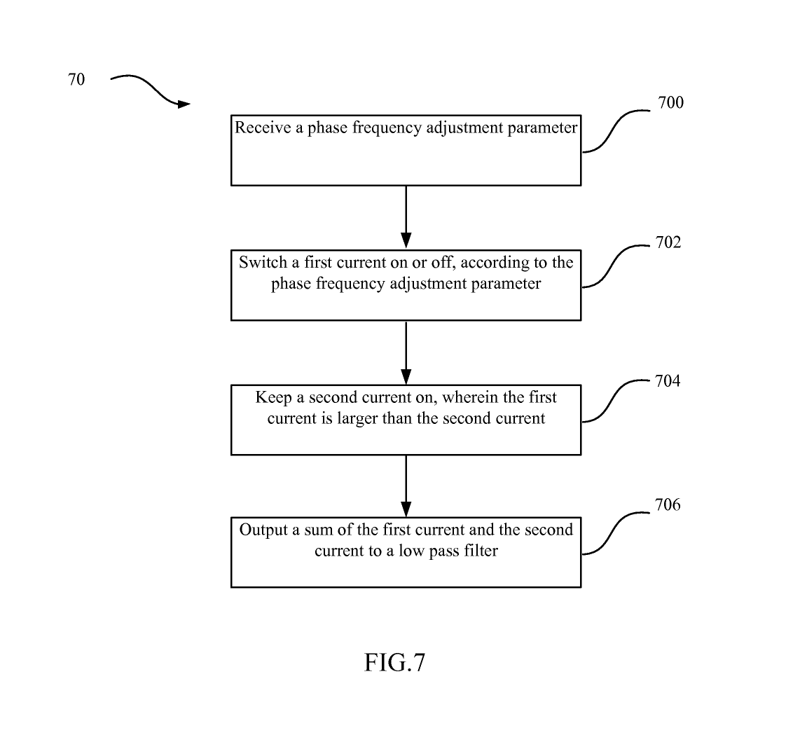

FIG. 7 shows a flow chart according to an embodiment of the present invention. A method 70 performed by a charge pump, comprises receiving (700) a phase frequency adjustment parameter. The method 70 further comprises switching (702) a first current on or off, according to the phase frequency adjustment parameter. The method 70 further comprises keeping (704) a second current on, wherein the first current is larger than the second current. The method 70 further comprises outputting (706) a sum of the first current and the second current to a low pass filter. Those skilled in the art can understand that the switching 702 and keeping 704 do not have to be performed in the order recited. That is to say switching 702 and keeping 704 can be implemented simultaneously, or asynchronously in different order.

Alternatively, the first current and the second current are configured to satisfy the following equation that the product of the value of the first current (I_{big}) and the minimum phase error (Pe(min)) is small than the product of the value of the second current (Iₛₘₐₗₗ) and the period of the reference signal (T_{ref}).

Alternatively, the first current is N times the second current.

It should be appreciated by those skilled in the art that components from different embodiments may be combined to yield another technical solution. This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

What is claimed is:

1. A charge pump comprising:
an input port configured to receive a phase frequency adjustment parameter;
a switch configured to switch a first current on or off, according to the phase frequency adjustment parameter, and keep a second current on, wherein the first current is larger than the second current; and
an output port configured to output a sum of the first current and the second current to a low pass filter; wherein the first current and the second current are configured to satisfy the following equation that
the product of the value of the first current (Ibig) and the minimum phase error (Pe(min)) is small than the product of the value of the second current (Ismall) and the period of the reference signal (Tref).

2. (canceled)

3. The charge pump of claim 1, wherein the first current is N times the second current.

4. The charge pump of claim 1 further comprising: a first current source (I0), a first NMOS (M10), a second NMOS (M12), a third NMOS (M14), a first PMOS (M16), a second PMOS (M18) and a PMOS switch (MUP),
wherein sources of the first PMOS and the second PMOS are both connected to a positive supply Voltage (VDD), gates of the first PMOS and the second PMOS and a drain of the second PMOS are all connected to a drain of the second NMOS, a drain of the first PMOS is connected to a source of the PMOS switch, gates of the second NMOS and the third NMOS, a drain of the third NMOS and a gate of the first NMOS are all connected to an output of the first current source,
sources of the first NMOS, the second NMOS and the third NMOS are all connected to a negative supply voltage (VSS), and a drain of the first NMOS is connected to a drain of the PMOS switch, the source of the PMOS switch is connected to the drain of the first PMOS, and a gate of the PMOS switch receives the phase frequency adjustment parameter, such that the PMOS switch switches on or off of the first PMOS, an output port of the charge pump is at the drain of the first NMOS.

5. The charge pump of claim 4, wherein width versus length ratio (W/L) of the first PMOS equals N times the width versus length ratio of the first NMOS, and width versus length ratios of the first NMOS, second NMOS, third NMOS and the second PMOS are the same.

6. The charge pump of claim 1 further comprising: a second current source (I1), a fourth NMOS (M20), a fifth NMOS (M22), a sixth NMOS (M24), a third PMOS (M26), a second PMOS (M28) and a NMOS switch (MDN),
wherein sources of the third PMOS and the fourth PMOS are both connected to a positive supply voltage(VDD), gates of the third PMOS and the fourth PMOS and a drain of the fourth PMOS are all connected to a drain of the fifth NMOS, a drain of the third PMOS is connected to a source of the NMOS switch(DN), gates of the fifth NMOS and the sixth NMOS, a drain of the sixth NMOS and a gate of the fourth NMOS are all connected to an output of the second current source, sources of the fourth NMOS, the fifth NMOS and the sixth NMOS are all connected to a negative supply voltage (VSS), and a drain of the fourth NMOS is connected to the source of the NMOS switch, a drain of the NMOS switch is connected to the drain of the third PMOS, and a gate of the PMOS switch receives the phase frequency adjustment parameter, such that the PMOS switch switches on or off of the fourth NMOS, and an output port of the charge pump is at the drain of the third PMOS.

7. The charge pump of claim 6, wherein width versus length ratio of the fourth NMOS equals N times the width versus length ratio of the third PMOS, and width versus length ratios of the fourth NMOS, the fifth NMOS, the sixth NMOS and the fourth PMOS are the same.

8. A method in a charge pump, comprising:
receiving a phase frequency adjustment parameter;
switching a first current on or off, according to the phase frequency adjustment parameter;
keeping a second current always on, wherein the first current is larger than the second current; and
outputting a sum of the first current and the second current to a low pass filter; wherein the first current and the second current are configured to satisfy the following equation that the product of the value of the first current (Ibig) and the minimum phase error (Pe(min)) is small than the product of the value of the second current (Ismall) and the period of the reference signal (Tref).

9. (canceled)

10. The method of claim 8, wherein the first current is of N times the second current.

11. A phase locked loop, comprising:
a phase frequency detector, configured to receive a first input signal and a second input signal, and to output a first phase frequency adjustment parameter and a second phase frequency adjustment parameter according to phase and frequency difference between the first input signal and the second input signal;
a charge pump coupled to the phase frequency detector, configured to receive one of the first phase frequency adjustment parameter and the second adjustment;
switch a first current on or off, according to the received phase frequency adjustment parameter;
keep a second current on, wherein the first current is larger than the second current; and
output a sum of the first current and the second current to a low pass filter;
the low pass filter configured to generate a voltage according to the sum of the first current and the second current, wherein the first current and the second current are configured to satisfy the following equation that the product of the value of the first current (Ibig) and the minimum phase error (Pe(min)) is small than the product of the value of the second current (Ismall) and the period of the reference signal(Tref);
a voltage controlled oscillator (VCO) coupled to the low pass filter, configured to generate an oscillation frequency according to the voltage;
a frequency divider configured to receive the oscillation frequency, to divide the oscillation frequency, and to generate the second input signal using the divided oscillation frequency.
